(19) United States
(12) Patent Application Publication
(10) Pub. No.: US 2026/0271357 A1
(43) Pub. Date: Sep. 10, 2026

(54) LATERAL HETEROJUNCTION BIPOLAR TRANSISTOR

(71) Applicant: GlobalFoundries U.S. Inc., Malta, NY (US)

(72) Inventors: Jacob Matthew DeAngelis, Burlington, VT (US); Uppili Srinivasan Raghunathan, Essex Junction, VT (US); Steven M. Shank, Jericho, VT (US); John J. Pekarik, Underhill, VT (US)

(21) Appl. No.: 19/073,389

(22) Filed: Mar. 7, 2025

(51) Int. Cl. H10D 62/17; H10D 10/01; H10D 10/60; H10D 62/13; H10D 62/822; H10D 84/01; H10D 84/63

(52) U.S. Cl. CPC H10D 62/184; H10D 10/021; H10D 10/60; H10D 62/134; H10D 62/136; H10D 62/137; H10D 62/822; H10D 84/0114; H10D 84/63

(57) ABSTRACT

The present disclosure relates to semiconductor structures and, more particularly, to lateral heterojunction bipolar transistors and methods of manufacture. The structure includes: a base region; a collector region on a first side of the base region; and an emitter region on a second side of the base region, wherein the collector region and the emitter region are above, below and laterally symmetrical about the base region.

### BACKGROUND

The present disclosure relates to semiconductor structures and, more particularly, to lateral heterojunction bipolar transistors and methods of manufacture.

A heterojunction bipolar transistor (HBT) is a type of bipolar junction transistor (BJT) which uses differing semiconductor materials for the emitter and base regions or collector and base regions, creating a heterojunction. HBTs are used in power amplifier and cellular applications, amongst others, and require low collector-base capacitance (Ccb), low base resistance (Rb), high cut-off frequencies (fT/fmax) and high breakdown voltage (BVceo). Current integration schemes for fabricating the HBT result in high Ccb (parasitic capacitance) and high Rb, which is a concern in bipolar technologies as it limits device scaling for improved fT/fmax.

### SUMMARY

In an aspect of the disclosure, a structure comprises: a base region; a collector region on a first side of the base region; and an emitter region on a second side of the base region, wherein the collector region and the emitter region are above, below and laterally symmetrical about the base region.

In an aspect of the disclosure, a structure comprises: a base region comprising an intrinsic base region and an extrinsic base region; a collector region on a first side of the base region; and an emitter region on a second side of the base region, wherein the collector region and the emitter region laterally and vertically overlap with the base region.

In an aspect of the disclosure, a method comprises: forming a base region; forming a collector region on a first side of the base region; and forming an emitter region on a second side of the base region, The collector region and the emitter region are formed above, below and laterally symmetrical about the base region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows an alternative structure in accordance with aspects of the present disclosure.

FIG. 3 shows another structure in accordance with aspects of the present disclosure.

FIGS. 4A-4C show respective fabrication processes for manufacturing the structure of FIG. 1 in accordance with aspects of the present disclosure.

### DETAILED DESCRIPTION

The present disclosure relates to semiconductor structures and, more particularly, to lateral heterojunction bipolar transistors and methods of manufacture. Advantageously, the lateral heterojunction bipolar transistors can be integrated with vertical heterojunction bipolar transistors. Moreover, the lateral heterojunction bipolar transistors provide THz level performance. In addition, the heterojunction bipolar transistors provide improved performance, e.g., higher fmax.

In more specific embodiments, the lateral heterojunction bipolar transistor (HBT) comprises identical and symmetrical collector and emitter regions. In embodiments, the emitter region and collector region vertically and laterally overlap with a base region, e.g., SiGe material of both an intrinsic base region (e.g., laterally overlap) and an extrinsic base region (e.g., vertically overlap). Moreover, no dielectric material is between the extrinsic base region and intrinsic base region, with the extrinsic base region being wider than the intrinsic base region. In further embodiments, an emitter/intrinsic base (EB) junction and collector/intrinsic base (CB) junction may comprise a crystal plane facet.

The lateral heterojunction bipolar transistors of the present disclosure can be manufactured in a number of ways using a number of different tools. In general, though, the methodologies and tools are used to form structures with dimensions in the micrometer and nanometer scale. The methodologies, i.e., technologies, employed to manufacture the lateral heterojunction bipolar transistors of the present disclosure have been adopted from integrated circuit (IC) technology. For example, the structures are built on wafers and are realized in films of material patterned by photolithographic processes on the top of a wafer. In particular, the fabrication of the lateral heterojunction bipolar transistors uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

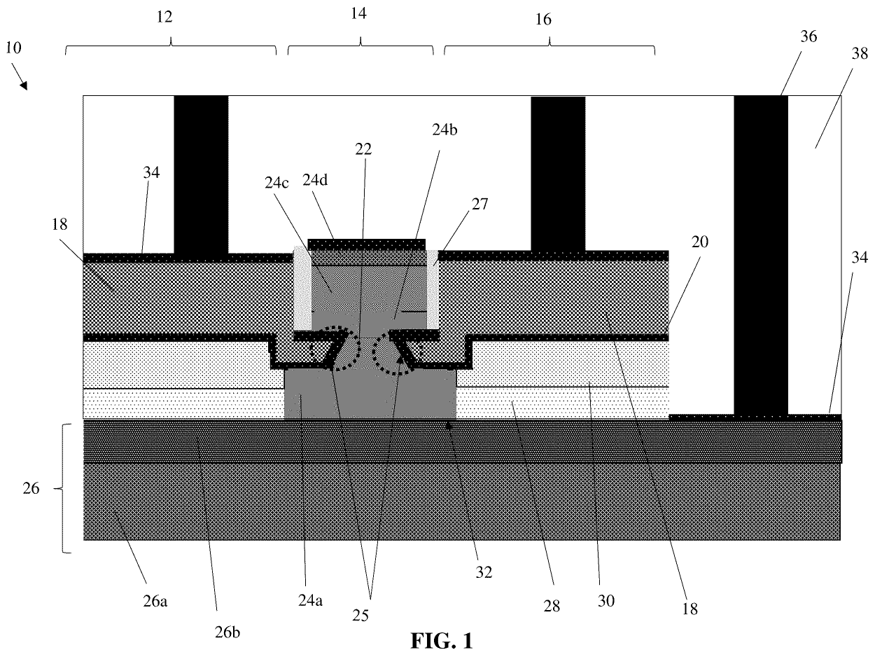

FIG. 1 shows a structure and respective fabrication processes in accordance with aspects of the present disclosure. More specifically, the structure 10 of FIG. 1 includes a lateral bipolar heterojunction comprising collector region 12, a base region 14 and an emitter region 16. The base region 14 may be provided between the collector region 12 and the emitter region 16. In embodiments, the base region 14 includes both the intrinsic base region and extrinsic base region.

As further shown in FIG. 1, the collector region 12 and the emitter region 16 may be symmetrical (about the base region 14) and may comprise identical materials, e.g., polysilicon material 18 and epitaxial semiconductor material 20. Moreover, the emitter region 16 and the collector region 12 may vertically and laterally overlap with the base region 14, e.g., SiGe material 22 of the intrinsic base region and SiGe material 24c of the extrinsic base region. In further embodiments, the emitter/base (EB) junction and the collector/base (CB) junction may have a crystal plane facet 25 due to an etching process of the semiconductor material 22 of the base region 14.

More specifically, the structure 10 includes a semiconductor substrate 26. In embodiments, the semiconductor substrate 26 is preferably bulk semiconductor material; although semiconductor-on-insulator technology is also contemplated herein. The semiconductor substrate 26 may be composed of any suitable material including, but not limited to, Si, SiGe, SiGeC, SiC, GaAs, InAs, InP, and other III/V or II/VI compound semiconductors. The semiconductor substrate 26 may comprise any suitable single crystallographic orientation (e.g., a (100), (110), (111), or (001) crystallographic orientation). In the SOI technology, from bottom to top, a handle substrate, a buried insulator layer (i.e., substrate) and a top semiconductor layer may be provided.

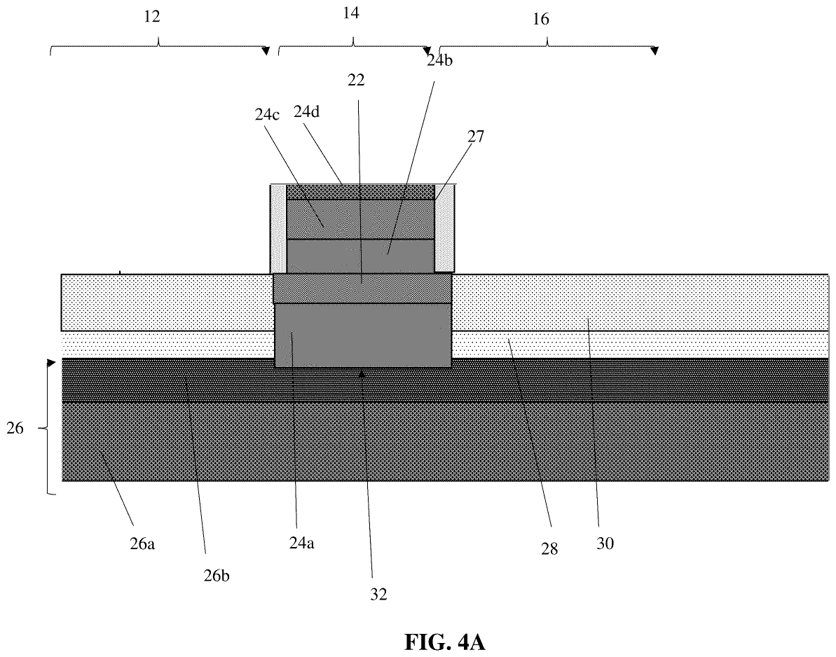

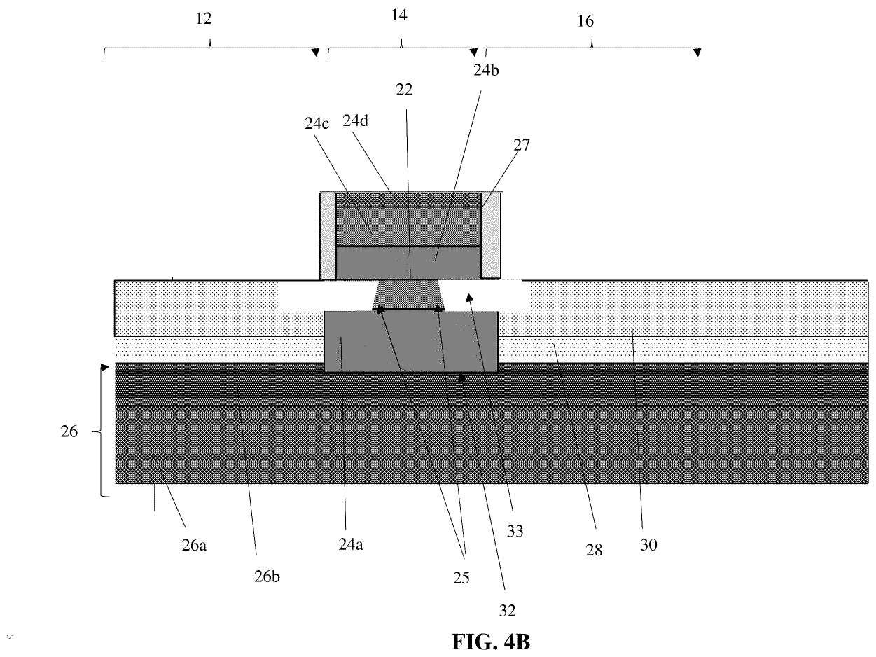

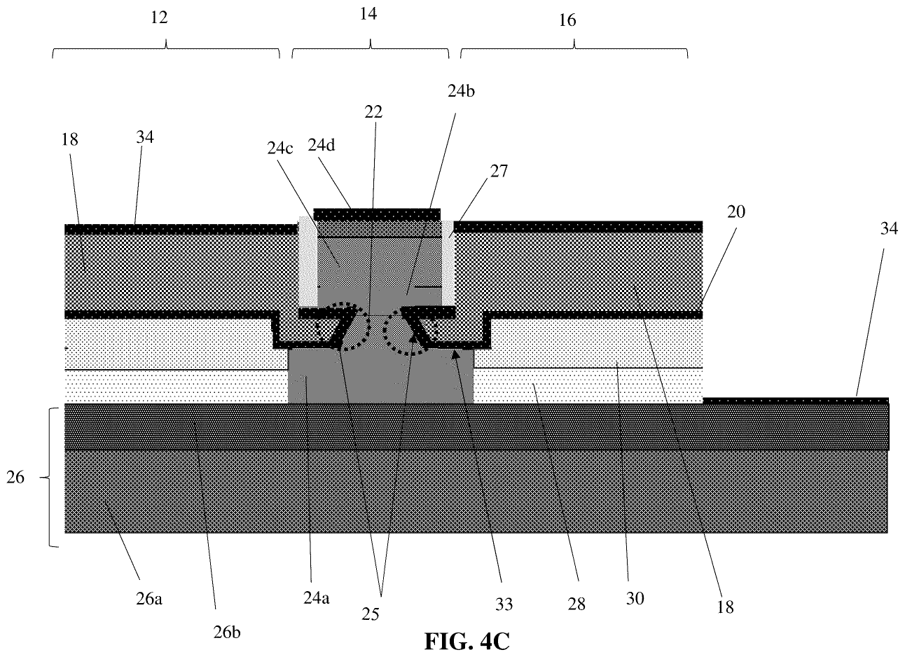

Still referring to FIG. 1, the semiconductor substrate 26 may include wells or implant regions 26a, 26b. In embodiments, the implant region 26a may be a triple well isolation structure; whereas the implant region 26b may be part of the extrinsic base region. The wells or implant regions 26a, 26b may be formed by introducing a dopant by, for example, ion implantation that introduces a concentration of a dopant in the semiconductor substrate 26 as described in more detail in FIG. 4A.

In embodiments, insulator materials 28, 30 may be formed over the implant region 26b. For example, the insulator material 28 may be oxide and insulator material 30 may be nitride; although other dielectric materials are also contemplated herein.

FIG. 1 further the base region 14 between the collector region 12 and the emitter region 16, in a lateral HBT structure. In embodiments, the base region 14 and the emitter region 15 are on the same plane. Also, the base region 14 may be an intrinsic base region and part of the extrinsic base region, comprising different semiconductor materials with varying dimensions, e.g., widths, located partly within and outside of a cavity 32 in insulator materials 28, 30. For example, the extrinsic base region, e.g., implant region 26b and SiGe materials 24c, 24d may be wider than the intrinsic base region, e.g., SiGe material 22. Also, in embodiments, different semiconductor materials may have varying dimensions, e.g., widths, located partly outside and above the cavity 32. Sidewall spacers 27 may be provided on sidewalls of the base region 14, e.g., extrinsic base region comprising semiconductor materials 24b, 24c, 24d. The sidewall spacers 27 may separate the base region 14 (e.g., extrinsic base region) from both the collector region 12 and the emitter region 16.

The base region 14 may comprise a stack of semiconductor materials 22, 24a, 24b, 24c, 24d. In embodiments, the semiconductor material 22 comprises the intrinsic base region and the semiconductor materials 24a, 24b, 24c, 24d comprise the extrinsic base region. In this example, the semiconductor materials 22, 24a may be formed within the cavity 32 and the remaining semiconductor materials 24b, 24c, 24d may be formed over the cavity 32. Also, in this example, there is no intervening dielectric material between any of the semiconductor materials 26b, 22, 24a, 24b, 24c, 24d.

The semiconductor material 24a may be intrinsic (undoped) Si material that is epitaxially grown within the cavity 32. The semiconductor material 24a may be selectively grown within the cavity 32 and on the semiconductor substrate 26. In embodiments, the epitaxial semiconductor material 22 may be selectively grown within the cavity 32 on the semiconductor material 24a. The epitaxial semiconductor material 22 may be, for example, single crystalline semiconductor material, e.g., SiGe material) comprising any suitable single crystallographic orientation (e.g., a (100), (110), (111), or (001) crystallographic orientation). In this way, the etching of the semiconductor material 22 will occur along a faceted plane resulting in an emitter/base (EB) junction and a collector/base (CB) junction with a crystal plane facet 25. In embodiments, the emitter/base (EB) junction and the collector/base (CB) junction are within the same plane.

The semiconductor material 24b may be selectively grown (e.g., epitaxially grown) on the semiconductor material 22. In embodiments, the semiconductor material 24b may be intrinsic (undoped) Si material. In addition, the semiconductor material 24c may be selectively grown (e.g., epitaxially grown) on the semiconductor material 24b, and the semiconductor material 24d may be non-selectively grown (e.g., epitaxially grown) on the semiconductor material 24d. The semiconductor materials 24c, 24d may be SiGe material. In embodiments, the semiconductor material 24b may also be doped SiGe material using an in-situ doping process. In embodiments, the dopant may be boron for an NPN device or arsenic or phosphorous for a PNP device.

In further embodiments, the semiconductor material 24a may have a dimension, e.g., width, larger than the width of the remaining the semiconductor materials 22, 24c, 24d, 24b. Moreover, the semiconductor materials 22, 24c, 24d, 24a, 24b may have a dimension, e.g., width, smaller than the width of the implanted region 26b, e.g., the extrinsic base. In addition, the semiconductor material 22 (e.g., intrinsic base) may have a narrower dimension, e.g., width, than the width of the semiconductor materials 24b, 24c, 24d (which form the extrinsic base), above the semiconductor material 22. This latter feature is due to an etching process of the semiconductor material 22, which forms the crystal plane facet 25 at the emitter/base (EB) junction and the collector/base (CB) junction.

FIG. 1 further shows the symmetrical collector region 12 and the emitter region 16 comprising identical materials, e.g., polysilicon material 18 and epitaxial semiconductor material 20. In embodiments, the semiconductor material 20 may be located between the insulator material 30 and the polysilicon material 18, in addition to between the polysilicon material 18 and the intrinsic base, e.g., semiconductor material 22. For example, in embodiments, the semiconductor material 20 may be epitaxially grown Si material that form at the crystal plane facet 25, thereby forming a faceted emitter/base (EB) junction and collector/base (CB) junction. In this way, a portion of the collector region 12 and the emitter region 16, e.g., the polysilicon material 18 and the semiconductor material 20, will extend between the semiconductor materials 24a, 24b and will be adjacent to the semiconductor material 22 (which is also sandwiched between the semiconductor materials 24a, 24b). And as already described herein, the emitter/base (EB) junction and the collector/base (CB) junction will have a crystal plane facet 25.

Silicide contacts 34 may be formed on the polysilicon material 18 of the collector region 12 and the emitter region 16, in addition to the semiconductor material 24d of the base region 14 and an exposed portion of the implant region 26b (e.g., extrinsic base). The silicide process is described with respect to FIG. 4C.

Contacts 36 may extend to and contact the silicide contacts 34. It should be understood by those of skill in the art that the contacts 36 may be a combination of via interconnects and wiring structures as is known in the art. The contacts 36 may be formed in interlevel dielectric material 38. The interlevel dielectric material 38 may be oxide, nitride of combinations thereof, deposited by a conventional deposition process, e.g., chemical vapor deposition (CVD). The contacts 36 may be formed by conventional lithography, etching and deposition processes as is known in the art such that no further explanation is required for a complete understanding of the present disclosure.

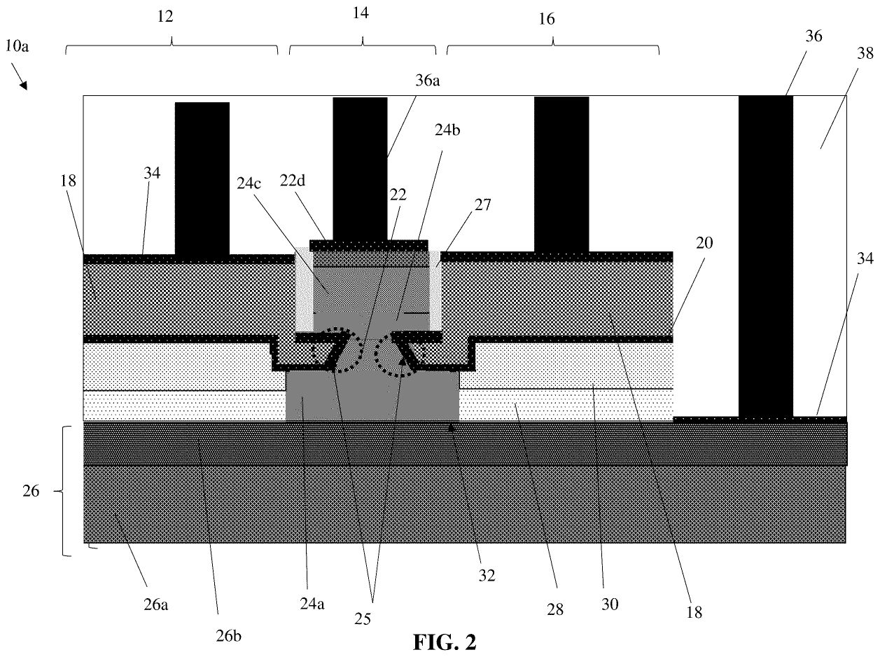

FIG. 2 shows an alternative structure in accordance with aspects of the present disclosure. In the structure 10a of FIG. 2, a contact 36a connects to the base region 14 in a same plane and between the contacts 36 connecting to the collector region 12 and emitter region 16. The contacts 36a may also be in the same plane as the contact 36 of implant region 26b. This structural relationship may be due to an improved overlay and minimum spacing between the emitter/base (EB) junction and collector/base (CB) junction. The remaining features of the structure 10a are similar to the structure 10 of FIG. 1.

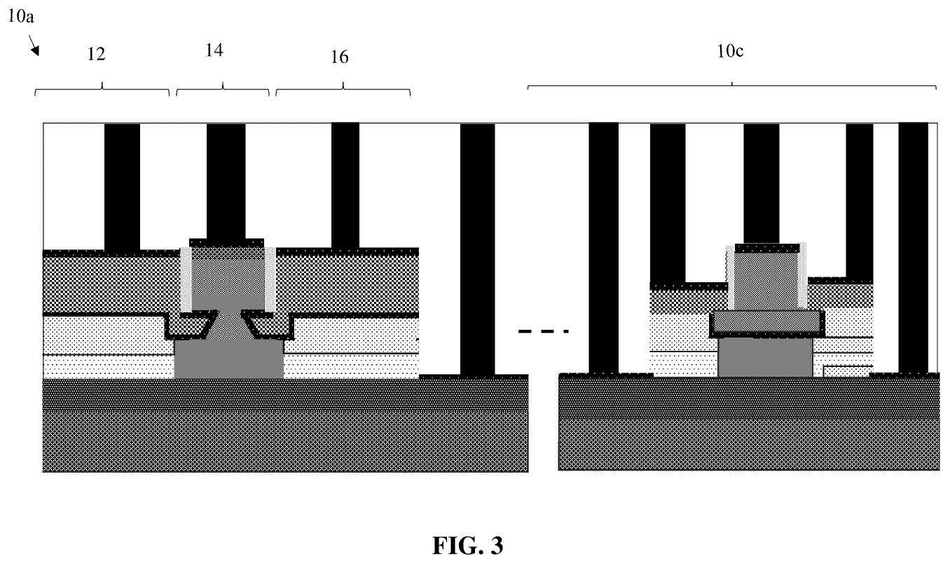

FIG. 3 shows another structure in accordance with aspects of the present disclosure. In the structure of FIG. 3, the lateral HBT 10a and a vertical HBT 10b may be integrated into a single structure. It should be recognized that the lateral HBT 10a and the vertical HBT 10b may include many of the same materials and can be fabricated using the same processes steps as described with respect to FIGS. 4A-4C. It should also be understood by those of ordinary skill in the art can integrate the lateral HBT 10A of FIG. 2 with the vertical HBT 10b shown in FIG. 3.

FIGS. 4A-4C show respective fabrication processes for manufacturing the structure 10 of FIG. 1 in accordance with aspects of the present disclosure. The fabrication processes described herein can also be used to manufacture the structures 10a, 10b shown in FIGS. 3B and 3C, as should be understood by those of skill in the art. It is also noted that the fabrication steps shown in FIGS. 4A-4C are non-limiting examples, with each figure showing combined fabrication processes as should be understood by those of skill in the art such that there is no need for including additional figures separately showing each and every manufacturing process.

Referring to FIG. 4A, the wells or implant regions 26a, 26b are formed in the semiconductor substrate 26. The wells or implant regions 26a, 26b may be formed by introducing a dopant by, for example, ion implantation that introduces a concentration of a dopant in the semiconductor substrate 26. For example, in an NPN-type device, the dopants for implant region 26a may be phosphorous or arsenic and the dopant for the implant region 26b may be boron. On the other hand, in a PNP-type device, the dopants for implant region 26b may be phosphorous or arsenic and the dopant for the implant region 26a may be boron.

In embodiments, respective patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions.

FIG. 4A further shows the formation of the insulator materials 28, 30 over the implant region 26b. The insulator material 28 may be oxide and insulator material 30 may be nitride, both of which may be formed by conventional deposition processes, e.g., CVD processes; although other dielectric materials are also contemplated herein.

A cavity 32 may be formed in the insulator materials 28, 30, exposing an upper surface of the semiconductor substrate 26, e.g., implant region 26b. The cavity 32 may be formed by conventional lithography, etching and deposition methods known to those of skill in the art. For example, a resist formed over the insulator material 30 is exposed to energy (light) and developed utilizing a conventional resist developer to form a pattern (opening). An etching process with a selective chemistry, e.g., reactive ion etching (RIE), will be used to transfer the pattern to form one or more trenches in the insulator materials 28, 30 through the openings of the resist. The etching will expose a surface of the semiconductor material 26 and, more particularly, implant region 26a. Following the resist removal by a conventional oxygen ashing process or other known stripants, the materials of the base region 14 can be deposited by deposition processes as described herein.

The stack of semiconductor materials 24a, 22 may be formed in the cavity 32 through epitaxial growth processes; whereas the stack of semiconductor materials 24b, 24c, 24d may be formed outside of the cavity 32 through epitaxially growth process over the stack of semiconductor materials 24a, 22. In embodiments, the semiconductor material 24a will be grown from the semiconductor substrate 26. Thereafter, the stack of semiconductor materials 24b, 24c, 24d may be patterned using conventional lithography and etching steps as already described herein. It is noted that semiconductor material 24d may also act as an extrinsic base of the vertical HBT 10c shown in FIG. 3C.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used. A dopant (n-type or p-type, as defined below) is typically added to the precursor gas or gas mixture.

Sidewall spacers 27 may be provided on sidewalls of the intrinsic base region, separating the base region 14 from both the collector region 12 and the emitter region 16. In the lateral HBT structure, the sidewall spacers 27 may be formed on the semiconductor materials 24b, 24c, 24d. To form the sidewall spacers 27, a nitride and/or oxide material may be blanket deposited (e.g., using CVD) over the structure, e.g., semiconductor materials 24b, 24c, 24d, followed by an anisotropic etching process.

The sidewall spacers 27 may also be formed in the same fabrication processes for both the lateral HBT structure and the vertical HBT shown 10c in FIG. 3C. To form the sidewalls spacers 27 in the vertical HBT shown 10c in FIG. 3C, a trench may be formed in the semiconductor material 24d over the emitter region of the vertical HBT shown 10c. This trench may be formed during the patterning process of the e.g., semiconductor materials 24b, 24c, 24d. Following the formation of the trench, the deposition and anisotropic etching processes described above may be performed.

In FIG. 4B, an undercut 33 may be formed under the semiconductor materials 24b, 24c, 24d. In more specific embodiments, the undercut 33 may be formed by a conventional lithography and selective etching processes of the semiconductor material 22. The etching process will follow the crystalline orientation (e.g., crystal grain) of the semiconductor material 22 resulting in crystal plane facets 25 (in a same plane). In embodiments, the etching process may be an HCl etching process.

In FIG. 4C, epitaxial semiconductor material 20 and polysilicon material 18 may be deposited over the structure shown in FIG. 4B, including within the undercut 33. In embodiments, the deposition of the epitaxial semiconductor material 20 and polysilicon material 18 will form an identical collector region 12 and the emitter region 16. In embodiments, the semiconductor material 20 may be epitaxially grown Si material on the sidewalls walls of the undercut 33 including at the crystal plane facet 25 which forms at the emitter/base (EB) junction and the collector/base (CB) junction. In embodiments, the epitaxial growth process may be a non-selective epitaxial growth process that forms a liner (e.g., does not completely fill in the undercut 33) and over the insulator material 30.

The polysilicon material 18 will fill in the remaining portions of the undercut 33 and will also form on the epitaxial semiconductor material 20 over the insulator material 30. The polysilicon material 18 may be planarized using a conventional CMP process. In embodiments, the polysilicon material 18 and epitaxial semiconductor material 20 formation processes can be shared with the vertical HBT 10a shown in FIG. 3.

Still referring to FIG. 4C, the polysilicon material 18, epitaxial semiconductor material 20 and insulator materials 28, 30 may be patterned to expose the underlying implant region 26. Silicide contacts 34 may be formed on the polysilicon material 18 of the collector region 12 and the emitter region 16, in addition to the semiconductor material 24d of the base region 14 and an exposed portion of the implant region 26b (e.g., extrinsic base).

As should be understood by those of skill in the art, the silicide process begins with deposition of a thin transition metal layer, e.g., nickel, cobalt or titanium, over fully formed and patterned regions 12, 14, 16, 26a. After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts 34 in the active regions of the device. It should be understood by those of skill in the art that silicide contacts will not be required on the devices, when a gate structure is composed of a metal material. The contacts and other remaining back end of line processes are shown and described with respect to FIG. 1.

The lateral heterojunction bipolar transistors can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a base region;
a collector region on a first side of the base region; and
an emitter region on a second side of the base region,
wherein the collector region and the emitter region are above, below and laterally symmetrical about the base region.

2. The structure of claim 1, wherein the base region comprises an intrinsic base region and an extrinsic base region comprising a stack of semiconductor materials.

3. The structure of claim 2, wherein the semiconductor material of the intrinsic base region is within a cavity in insulator material and between the semiconductor materials of the extrinsic base.

4. The structure of claim 3, further comprising:
a first crystal plane facet at a junction at semiconductor material of the collector region and the semiconductor material of the intrinsic base region; and
a second crystal plane facet at a junction at semiconductor material of the emitter region and the semiconductor material of the intrinsic base region.

5. The structure of claim 4, wherein the first crystal plane facet and the second crystal plane facet are below the semiconductor materials of the extrinsic base region.

6. The structure of claim 5, wherein the semiconductor material of the intrinsic base region comprises SiGe material between intrinsic Si material of the extrinsic base region and below SiGe material of the extrinsic base region.

7. The structure of claim 2, wherein the emitter region and the collector region vertically and laterally overlap with the semiconductor materials of the extrinsic base region.

8. The structure of claim 2, wherein the semiconductor material of the intrinsic base region and the semiconductor materials of the extrinsic base region are stacked on top of one another and devoid of any intervening dielectric material.

9. The structure of claim 2, wherein the semiconductor materials of the extrinsic base region are wider than the semiconductor material of the intrinsic base.

10. The structure of claim 1, wherein the structure comprises a lateral heterojunction bipolar transistor integrated with a vertical heterojunction bipolar transistor on a same semiconductor substrate.

11. A structure comprising:
a base region comprising an intrinsic base region and an extrinsic base region;
a collector region on a first side of the base region; and
an emitter region on a second side of the base region,
wherein the collector region and the emitter region laterally and vertically overlap with the base region.

12. The structure of claim 11, wherein the intrinsic base region and the extrinsic base region comprise a stack of semiconductor materials devoid of any insulator material therebetween.

13. The structure of claim 12, wherein the semiconductor material of the intrinsic base region is within a cavity in insulator material above a common semiconductor substrate.

14. The structure of claim 11, further comprising:
a first crystal plane facet at a junction of the collector region and the intrinsic base region; and
a second crystal plane facet at a junction of the emitter region and the intrinsic base region.

15. The structure of claim 14, wherein the first crystal plane facet and the second crystal plane facet are formed within single crystalline semiconductor material of the intrinsic base region, below semiconductor materials of the extrinsic base region.

16. The structure of claim 15, wherein the single crystalline semiconductor material of the intrinsic base region is narrower than the semiconductor materials of the extrinsic base region.

17. The structure of claim 11, wherein the collector region and the emitter region comprise identical materials and are in a same plane.

18. The structure of claim 11, wherein the collector region and the emitter region comprise semiconductor material within an undercut of semiconductor material of the intrinsic base region and between semiconductor materials of the extrinsic base region.

19. The structure of claim 11, wherein the structure comprises a lateral heterojunction bipolar transistor integrated with a vertical heterojunction bipolar transistor on a same semiconductor substrate.

20. A method comprising:
forming a base region;
forming a collector region on a first side of the base region; and
forming an emitter region on a second side of the base region,
wherein the collector region and the emitter region are formed above, below and laterally symmetrical about the base region.
